(19) United States
(12) Patent Application Publication
(10) Pub. No.: US 2017/0271612 A1
(43) Pub. Date: Sep. 21, 2017

(54) DISPLAY DEVICE

(71) Applicant: Japan Display Inc., Tokyo (JP)

(72) Inventor: Komei MATSUZAWA, Tokyo (JP)

(21) Appl. No.: 15/416,007

(22) Filed: Jan. 26, 2017

(30) Foreign Application Priority Data
Mar. 18, 2016 (JP) 2016-055023

(51) Int. Cl. H01L 51/52; H01L 51/50

(52) U.S. Cl. CPC H01L 51/5228; H01L 51/5012; H01L 51/5218; H01L 51/5234; H01L 2251/305; H01L 2251/5315; H01L 2251/558

(57) ABSTRACT

A display device in an embodiment according to the present invention includes a first electrode, an insulation layer including an opening region exposing an inner side region of the first electrode, and a cover region covering regions apart from an inner side region of the first electrode, an end part of the cover region overlapping with a periphery edge part of the first electrode, an organic layer above the first electrode, a second electrode arranged opposite the first electrode and corresponding to the opening region of the insulation layer above the organic layer, and a conductive layer above the cover region of the insulation layer and at least a part of the second electrode and the conductive layer are in contact.

### CROSS REFERENCE TO RELATED APPLICATIONS

This application is based upon and claims the benefit of priority from the prior Japanese Patent Application No. 2016-055023, filed on Mar. 18, 2016, the entire contents of which are incorporated herein by reference.

### FIELD

One embodiment of the present invention is related to a structure of a pixel part arranged with a pixel in a display device.

### BACKGROUND

An organic electroluminescence element has a structure arranged with an organic layer including an organic electroluminescence material above a lower electrode, and an upper electrode is arranged above the organic layer. In a display device formed with a pixel using such an organic electroluminescence element, one of a lower electrode and an upper electrode serves as a transparent electrode. For example, a material such as indium tin oxide is used in the case where an upper electrode arranged above an organic layer is set as the transparent electrode. Since a transparent conductive film has high resistance compared to a metal layer such as aluminum, a sufficient voltage can't be applied to an organic electroluminescence element due to the effects of a drop in voltage at a center part of a pixel region which leads to a drop in luminosity. As a result, a structure in which an auxiliary electrode is arranged using a metal layer in a transparent conductive layer used as an upper electrode is disclosed (for example, see Japanese Laid Open Patent Publication No. 2008-084541).

### SUMMARY

A display device in an embodiment according to the present invention includes a first electrode, an insulation layer including an opening region exposing an inner side region of the first electrode, and a cover region covering regions apart from an inner side region of the first electrode, an end part of the cover region overlapping with a periphery edge part of the first electrode, an organic layer above the first electrode, a second electrode arranged opposite the first electrode and corresponding to the opening region of the insulation layer above the organic layer, and a conductive layer above the cover region of the insulation layer and at least a part of the second electrode and the conductive layer are in contact.

A display device in an embodiment according to the present invention includes a plurality of pixels, a pixel region including the plurality of pixels. Each of the plurality of pixels includes a light emitting element stacked with a first electrode, an insulation layer and a second electrode. The pixel region includes an insulation layer in each of the plurality of pixels, the insulation layer having an opening region exposing an inner side region of the first electrode and a cover region covering regions apart from an inner side region of the first electrode, an end part of the cover region overlapping with a periphery edge part of the first electrode, and a conductive layer extending along the plurality of pixels above the cover region of the insulation layer; the second electrode and the conductive layer being electrically connected.

### BRIEF DESCRIPTION OF DRAWINGS

FIG. 1 is a perspective view diagram showing an external appearance of a display device related to one embodiment of the present invention;

FIG. 2 is a planar view diagram showing a structure of a pixel in a display device related to one embodiment of the present invention;

FIG. 3 is a cross-sectional diagram showing a structure of a pixel part of a display device related to one embodiment of the present invention;

FIG. 4 is a cross-sectional diagram for schematically explaining a manufacturing method of a display device related to one embodiment of the present invention;

FIG. 5 is a planar view diagram showing a structure of a pixel part in a display device related to one embodiment of the present invention;

FIG. 6 is a cross-sectional diagram showing a structure of a pixel part in a display device related to one embodiment of the present invention;

FIG. 7 is a cross-sectional showing a structure of a pixel part in a display device related to one embodiment of the present invention;

FIG. 8 is a cross-sectional diagram showing a structure of a pixel part in a display device related to one embodiment of the present invention;

FIG. 9 is a planar view diagram showing a structure of a pixel part in a display device related to one embodiment of the present invention;

FIG. 10 is a planar view diagram showing a structure of a pixel part in a display device related to one embodiment of the present invention;

FIG. 11 is a planar view diagram showing a structure of a pixel part in a display device related to one embodiment of the present invention;

FIG. 12 is a planar view diagram showing a structure of a pixel part in a display device related to one embodiment of the present invention;

FIG. 13 is a planar view diagram showing a structure of a pixel part in a display device related to one embodiment of the present invention;

FIG. 14 is a planar view diagram showing a structure of a pixel part in a display device related to one embodiment of the present invention;

FIG. 15 is a planar view diagram showing a structure of a pixel part in a display device related to one embodiment of the present invention; and

FIG. 16 is a schematic diagram for explaining a state when foreign objects are attached to a pixel part in a display device.

### DESCRIPTION OF EMBODIMENTS

The embodiments of the present invention are explained below while referring to the diagrams. However, it is possible to perform the present invention using various different forms, and the present invention should not be limited to the content described in the embodiments exemplified herein. Although the width, thickness and shape of each component are shown schematically compared to their actual form in order to better clarify explanation, the drawings are merely an example and should not limit an interpretation of the present invention.

In the specification and each drawing, the same reference symbols are attached to similar elements and elements that have been mentioned in previous drawings, and therefore a detailed explanation may be omitted where appropriate. Notations such as “a” and “b” attached to the end of a symbol are sometimes used to identify the same element. Furthermore, the characters “first” and “second” attached to each element are convenient labels used for distinguishing each element and do not contain any further meaning unless otherwise explained.

In the present specification, in the case where certain parts or regions are given as “above (or below)” other parts or regions, as long as there is no particular limitation, these include parts which are not only directly above (or directly below) other parts or regions but also in an upper direction (or lower direction). That is, in the case where certain parts or regions are given as “above (or below)” other parts or regions, other structural elements may be included between other parts or regions in an upper direction (or lower direction).

In the present invention, the display device includes a first substrate. The first substrate has at least one flat main surface and is formed with a layer structure in which a plurality of layers is arranged above this one main surface. In the explanation below, the one main surface of the first substrate is used as a reference and, in cross sectional view, the upper side of this one main surface is explained as “upper layer”, “upwards” or “upper surface”.

In a display device with an electroluminescence element arranged in a pixel, a structure is known in which an upper electrode having translucency is arranged above an organic layer, a lower electrode arranged in each pixel and light is emitted from the organic layer and passed though the upper electrode. In this case, the upper electrode is a transparent conductive layer and is arranged on roughly the entire surface of a pixel part. Since the upper electrode reduces the effects of a drop in voltage due to resistance loss, a low sheet resistance is desired. A transparent conductive layer is manufactured by a sputtering method and the like and its low resistivity is achieved by control of the manufacturing conditions.

A transparent conductive layer is a metal oxide whose resistivity can not be lowered like a pure metal such as aluminum. Therefore, it is necessary to increase the layer thickness of a transparent conductive layer used as an upper electrode in order to reduce sheet resistance.

However, when the layer thickness of a transparent conductive layer is increased, the size of foreign objects attached to the depositing surface is also increased. Thus, it is cause that an organic electroluminescence element can not be sufficiently sealed by a passivation layer. When coverage of an organic electroluminescence element by a passivation layer is insufficient, the organic electroluminescence element deteriorates due to the infiltration of water. As a result, non-light emitting pixels (also called [dark spots] since they appear black in a display) are produced in a display device which is a cause of display defects.

A present embodiment explained below discloses a display device which can reduce the occurrence of display defects.

### 1. Summary of Display Device

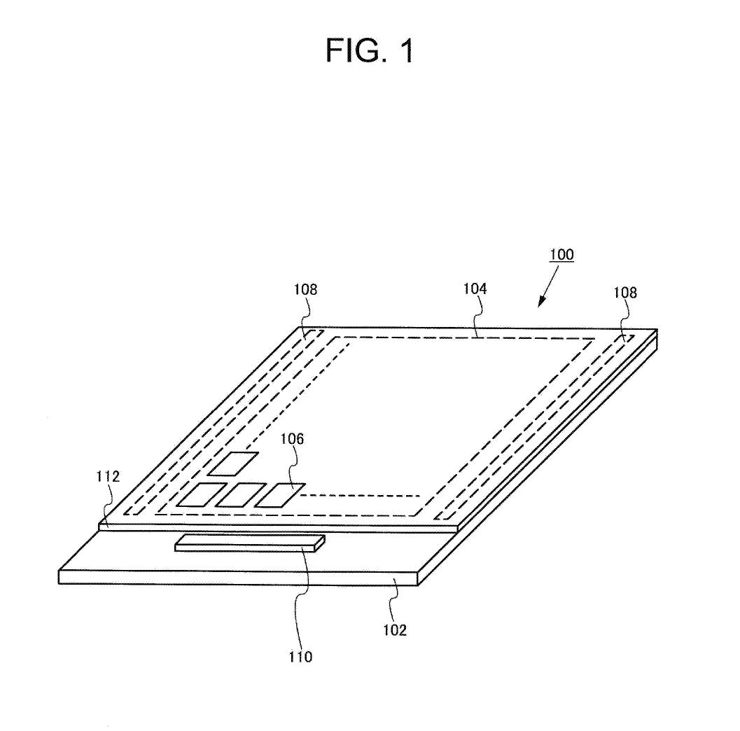

FIG. 1 shows a perspective view of a display device 100 related to one embodiment of the present invention. The display device 100 includes a pixel part 104 arranged with a plurality of pixels 106. The pixel part 104 is arranged on one main surface of a substrate 102. A sealing member 112 is arranged on the main surface of the substrate 102. The pixel part 104 is sealed by the sealing member 112. The sealing member 112 is a plate shaped or layer shaped form. Glass or an organic resin material is used for the sealing member 112. In addition, the display device 100 may also be arranged with a first drive circuit 108 which outputs a scanning signal, and a second drive circuit 110 which outputs a video signal with respect to the pixel part 104.

Glass or an organic resin and the like are applied as the material of the substrate 102. The display device 100 has flexibility in the case where the substrate 102 is formed by the organic resin. For example, it is possible to use an organic resin layer as the substrate 102. It is possible to use a polyimide layer as an example of an organic resin layer. In the case where the substrate 102 has flexibility, the sealing member 112 may be a resin material or a stacked body of an inorganic material and organic resin material to also provide flexibility for the display device 100. For example, the sealing member 112 is formed by a stacked body of a silicon nitride layer and polyimide layer. Here, in the case where the display device 100 is a top-emission type device, a PET (polyethylene-telephthalate) layer, PEN (polyethylene naphthalate) layer, or PC (polycarbonate) layer and the like may be used instead of a polyimide layer since a high level of transparency is demanded for the sealing member 112.

### 2. Pixel Structure

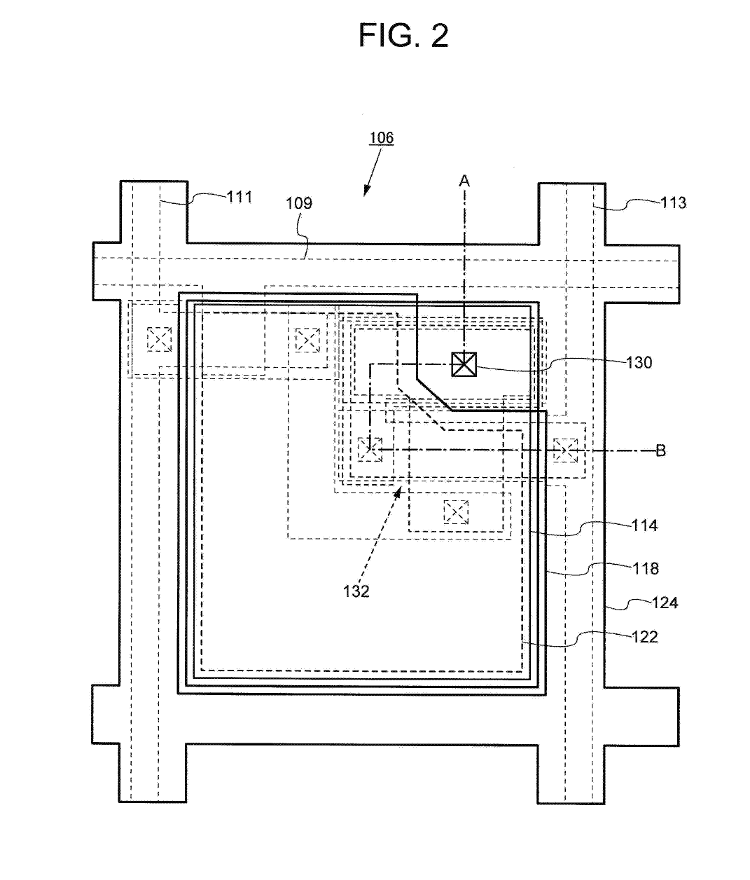

FIG. 2 shows a planar view of a pixel 106 arranged in the display device 100. The pixel 106 includes a structure in which a plurality of layers is stacked. FIG. 2 includes a structure in which a first electrode 114 and second electrode 118 are stacked from a lower layer side. In addition, FIG. 2 shows a form in which the second electrode 118 and a conductive layer 124 is arranged in contact with at least a part of the second electrode 118. Furthermore, not shown in FIG. 2, the pixel 106 is arranged with the first electrode 114, the second electrode 118, and an organic layer 116 including a light emitting material and between the first electrode 114 and the second electrode 118. That is, a light emitting element stacked with the first electrode 114, organic layer 116 and the second electrode 118 is arranged in the pixel 106. For example, an organic electroluminescence material is used as the light emitting material. In addition, an insulation layer including an opening part is arranged in the pixel part 104. The insulation layer includes an open region for exposing an inner side region of the first electrode 114 and a cover region which is apart from the open region. The cover region covers a periphery edge part of the first electrode 114. FIG. 2 shows an end part 122 of the cover region of the insulation layer by a dotted line.

The pixel 106 has a structure in which the first electrode 114 overlaps the second electrode 118 via an organic layer in a region (open region) that is inside of the end part 122 of the cover region of the insulation layer. This overlapping part serves as a light emitting region.

The conductive layer 124 is arranged over the cover region of the insulation layer. The end part of the conductive layer 124 is arranged inside the end part 122 of the cover region of the insulation layer. That is, the conductive layer 124 is arranged to the outer side of the light emitting region. At least a part of the end part of the second electrode 118 expands further to the outer side than the light emitting region. The second electrode 118 contacts with the conductive layer 124 at the end part or end part vicinity (end part region) of the insulation layer above the insulation layer. That is, at least a part of the second electrode 118 contacts with the conductive layer 124. In this way, the second electrode 118 and conductive layer 124 are in an electrically connected state.

The first electrode 114 is electrically connected via a contact hole 130 with a drive element 132 arranged on a lower layer than the first electrode 114. The contact hole 130 is arranged near to an end part of the first electrode 114 and is buried by an insulation layer covering a periphery edge part of the first electrode 114.

Furthermore, FIG. 2 shows a scanning signal line 109, video signal line 111 and power supply line 113 arranged on a lower layer than the first electrode 114 by a dotted line. The scanning signal line 109, video signal line 111 and power supply line 113 are buried by a leveling layer or interlayer insulation layer arranged on a lower layer of the first electrode 114. In the example shown in FIG. 2, the scanning signal line 109 is arranged in a first direction and the video signal line 111 and power supply line 113 are arranged in a second direction intersecting the first direction. The conductive layer 124 is arranged in a region overlapping a region in which the scanning signal line 109, video signal line 111 and power supply line 113 are arranged.

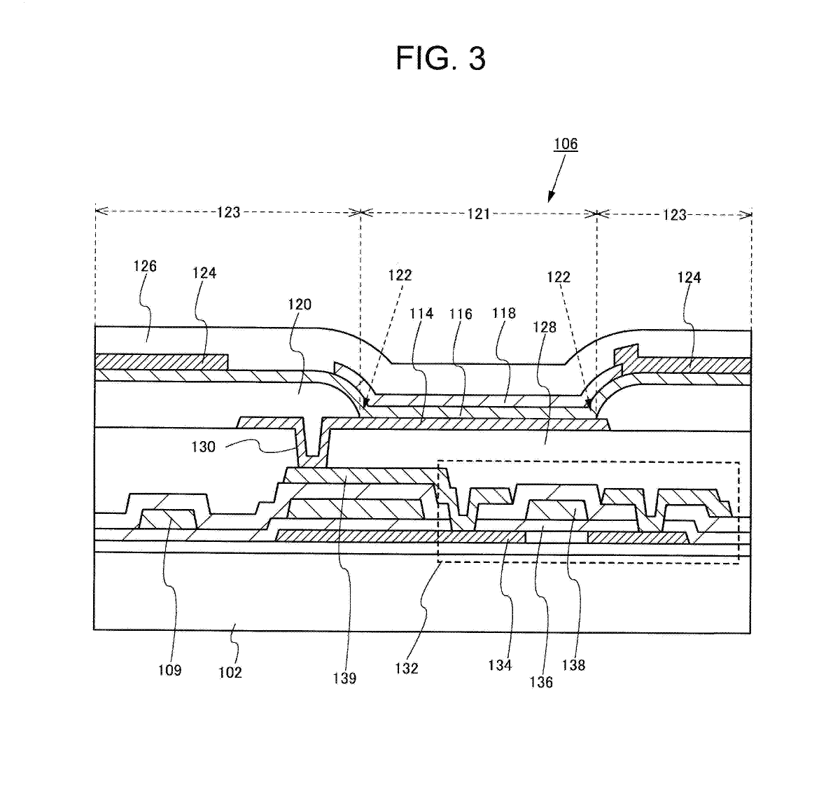

A cross-sectional structure along the line A-B shown in FIG. 2 is shown in FIG. 3. As is shown in FIG. 3, the pixel 106 has a region in which the first electrode 114, organic layer 116 and second electrode 118 are stacked and overlap. As previously mentioned, this overlapping part serves as a light emitting region in the pixel 106.

The first electrode 114 is arranged above the leveling layer 128. The leveling layer 128 is formed from an insulation material and the surface on which the first electrode 114 is arranged is approximately smooth. For example, an organic resin material such as polyimide or acrylic and the like is used as the insulation material of the leveling layer 128. The first electrode 114 is electrically connected with the drive element 132 via a contact hole 130 arranged in the leveling layer 128.

Furthermore, an example of the drive element 132 is a transistor. And the thin film transistor formed with a channel in a semiconductor layer can be applied, for example. The thin film transistor has a structure in which a semiconductor layer 134, gate insulation layer 136 and gate electrode 138 are stacked, and a source/drain electrode 139 which is electrically connected with one of a source region or drain region formed in the semiconductor layer 134 is electrically connected with the first electrode 114 via the contact hole 130 arranged in the leveling layer 128. A silicon semiconductor (polycrystalline silicon, amorphous silicon etc.) or oxide semiconductor is used as the semiconductor layer 134. A voltage of the first electrode 114 is controlled by the drive element 132 which is electrically connected with the first electrode 114.

An insulation layer 120 is arranged above the leveling layer 128 and first electrode 114. The insulation layer 120 includes an open region 121, which exposes an inner side region of the first electrode 114, and a cover region 123, which covers regions other than an inner side region of the first electrode 114. An end part 122 of the cover region 123 of the insulation layer 120 overlaps a periphery edge part of the first electrode 114. In addition, the contact hole 130 is buried by the insulation layer 120. The organic layer 116 is arranged from an upper surface of the first electrode 114 along a surface of the insulation layer 120 (that is, surface of the cover region 123). There is no limitation to the structure of the organic layer 116 in the present embodiment. For example, the organic layer 116 may be formed of a low molecular or high molecular organic material. In the case of a low molecular organic material, in addition to a light emitting layer including an organic material with light emitting properties, the organic layer 116 may also include a hole injection layer and electron injection layer sandwiching the light emitting layer. Furthermore, the organic layer 116 may include a hole transport layer and electron transport layer sandwiching the light emitting layer.

The conductive layer 124 is arranged above the cover region of the insulation layer 120. That is, the conductive layer 124 is arranged in a region that is inside of the end part 122 of the cover region 123 of the insulation layer 120, does not overlap with a light emitting region of a pixel 106 and is arranged on an upper layer side of the insulation layer 120. The conductive layer 124 extends in at least one direction and is arranged to link with a plurality of pixels. It is preferred that the conductive layer 124 is arranged to enclose a light emitting region of a pixel 106.

The second electrode 118 is arranged on an upper surface of the organic layer 116. At least one end of the second electrode 118 is arranged to contact with the conductive layer 124. That is, the second electrode 118 and conductive layer 124 are arranged to contact in a region overlapping the insulation layer 120. It is sufficient that at least one part of the second electrode 118 and conductive layer 124 are in contact. For example, the second electrode 118 is arranged so that an end part contacts with an end part of the conductive layer 124. In this way, the second electrode 118 and conductive layer 124 are electrically connected (are in a conductive state). An end part in the cover region of the insulation layer 120 includes an inclined surface in a cross-sectional view. The second electrode 118 is arranged along the inclined surface of the insulation layer 120 from an upper surface region of the first electrode 114. In addition, the conductive layer 124 is preferred to be arranged from a top surface of the insulation layer 120 to the inclined surface. With such a structure, it is possible to contact the second electrode 118 and conductive layer 124 at the inclined surface of the insulation layer 120. In this way, the connection of second electrode 118 and conductive layer 124 are not cut by a step produced by the thickness of the insulation layer 120. It means that it is possible to form a good contact with second electrode 118 and conductive layer 124.

The second electrode 118 is arranged in each pixel corresponding to the first electrode 114. Although the second electrode 118 is independently arranged in each pixel, voltage control is possible by connecting the second electrode 118 with the conductive layer 124.

In the present embodiment, the second electrode 118 is an electrode with translucency and the first electrode 114 is an electrode having light reflecting properties (includes a light reflective surface). For example, the second electrode 118 having translucency can be formed by a transparent conductive layer. Or the second electrode 118 may be formed by a metal thin layer which allows light to pass through. For example, a metal oxide cover layer such as indium tin oxide (also called “ITO” herein) or indium zinc oxide (also called “IZO” herein) is used as the transparent conductive layer. In addition, the second electrode 118 may be formed using a silver nanowire or graphene.

In this case, the first electrode 114 is formed using a metal material. The first electrode 114 includes light reflecting properties by being formed using a metal material. For example, the first electrode 114 may have a structure in which a transparent conductive layer and a metal layer are stacked. For example, the first electrode 114 can be formed by at least two transparent conductive layers and a metal layer (a material with high reflectance such as silver (Ag) or aluminum (Al) is preferred) sandwiched between the two transparent conductive layers. With such a structure, it is possible to reflect light emitted by the organic layer 116 to the second electrode 118 side.

The conductive layer 124 is formed from a metal material. Tungsten (W), molybdenum (Mo), aluminum (Al) and titanium (Ti) and the like are exemplified as metal materials that can be applied to the conductive layer 124. The conductive layer 124 is formed by a cover layer of one of these metal materials or an alloy material such as molybdenum-tungsten. In addition, the conductive layer 124 may be formed by a layer including conductive particles such as a silver paste. In either case, it is preferred that the conductive layer 124 is formed as a layer with a lower resistance than the second electrode 118.

In a conventional display panel, an electrode corresponding to a second electrode is formed on an entire surface of a pixel part. In the case where a metal oxide thin layer such as ITO or IZO is used as an electrode corresponding to a second electrode, a layer thickness of the second electrode is set so that sheet resistance becomes a few Ω/sq. to a few tens of Ω/sq. This is because when sheet resistance of an electrode is high, the effects of a drop in voltage can no longer be ignored, and it is no longer possible to obtain a display with light uniformity within a screen. Although a resistance value changes depending on the manufacture conditions of an ITO layer or IZO layer, normally a layer thickness larger than 100 nm is necessary in order to realize the previously mentioned sheet resistance. For example, even in a display panel having a screen size of about five inches, the layer thickness of a second electrode having translucency is required to be 200 nm or more in order to realize the previously mentioned sheet resistance.

On the other hand, in the present embodiment, the second electrode 118 is arranged in each pixel 106 and is connected via the conductive layer 124. As a result, the conductive layer 124 with low resistance serves as an auxiliary electrode, and sheet resistance of the second electrode 118 drops when the entire pixel part 104 is considered. As a result, it is possible to form the second electrode 118 into a thin layer. In the present embodiment, for example, the layer thickness of the second electrode 118 can be set from 50 nm to 100 nm in order to achieve a thin layer.

When the second electrode 118 is formed using a conductive metal oxide such as an ITO layer or IZO layer, a sputtering method is used as the thin layer manufacturing technique. Although a sputtering method is suitable for manufacture of a conductive thin layer, management is necessary of foreign objects (particles) which are produced when sputtering a target to form a layer.

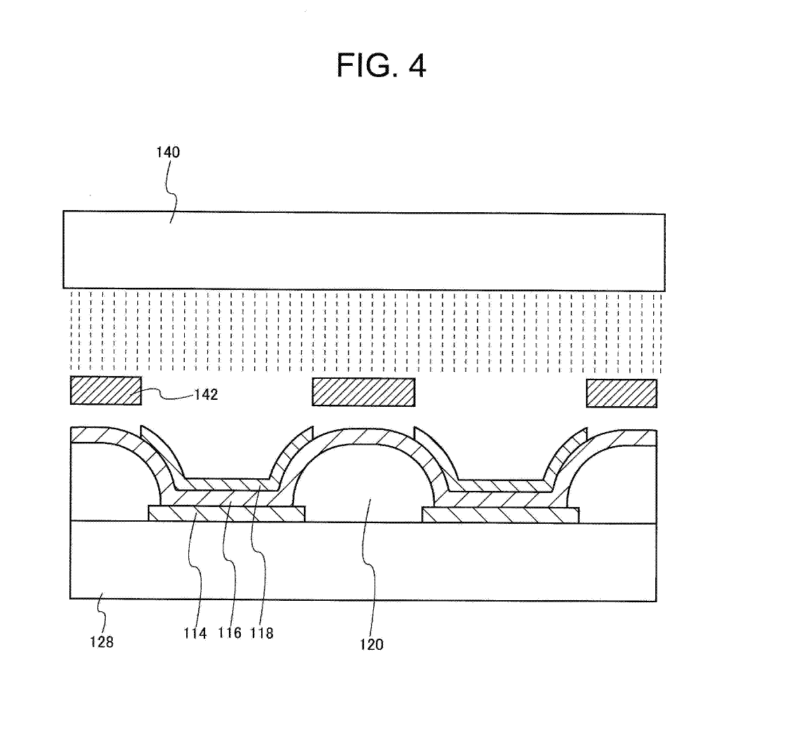

In the present embodiment, as is shown in FIG. 4, when a sputtering method is used as the manufacturing method of the second electrode 118, a shadow mask 142 including opening parts in a region corresponding to the first electrode 114 is placed between the substrate 102 and a sputtering target 140. In this way, a region between adjacent pairs of pixels in the substrate 102 formed with a pixel 106 is covered by the shadow mask 142, and a cover layer is formed by sputtering only in the minimum required regions where the second electrode 118 should be formed. Thus, it is possible to suppress foreign objects being attached to the deposition surface of the substrate 102.

Furthermore, in this embodiment, since it is possible to reduce the thickness of the second electrode 118, it is possible to shorten the layer formation time by sputtering. Even in this case, it is possible to suppress foreign objects being attached to the deposition surface of the substrate 102. In addition, since the size of foreign objects also decreases by reducing the thickness of the second electrode 118, it is possible to sufficiently cover the second electrode 118 by the passivation layer 126, and it is possible to suppress the occurrence of gaps in a passivation layer 926 described herein and suppress the occurrence of display defects due to cracks.

Resistivity of a metal material used as the conductive layer 124 is about 5.6 μΩcm in the case of tungsten, about 4.8 μΩcm in the case of molybdenum, about 2.7 μΩcm in the case of aluminum, and about 70 μΩcm in the case of titanium, which are sufficiently low resistances compared to a conductive metal oxide such as ITO or IZO. As a result, the thickness of the conductive layer 124 is 200 nm or less, preferably from 2 nm to 120 nm. Since the second electrode 118 is thinner than the conductive layer 124, it is possible to cover an end region of the second electrode 118 and ensure that cracks due not occur in a step part.

As is shown in FIG. 3, a passivation layer 126 is arranged in an upper layer of the second electrode 118 and conductive layer 124. An insulation layer having gas barrier properties in order to protect the organic layer 116 is used for the passivation layer 126. For example, a silicon nitride layer or aluminum oxide layer and the like are used as the passivation layer 126. The passivation layer 126 has a sufficient thickness for protecting the organic layer 116. The thickness of the passivation layer 126 is 200 nm or more, preferably from 500 nm to 1000 nm.

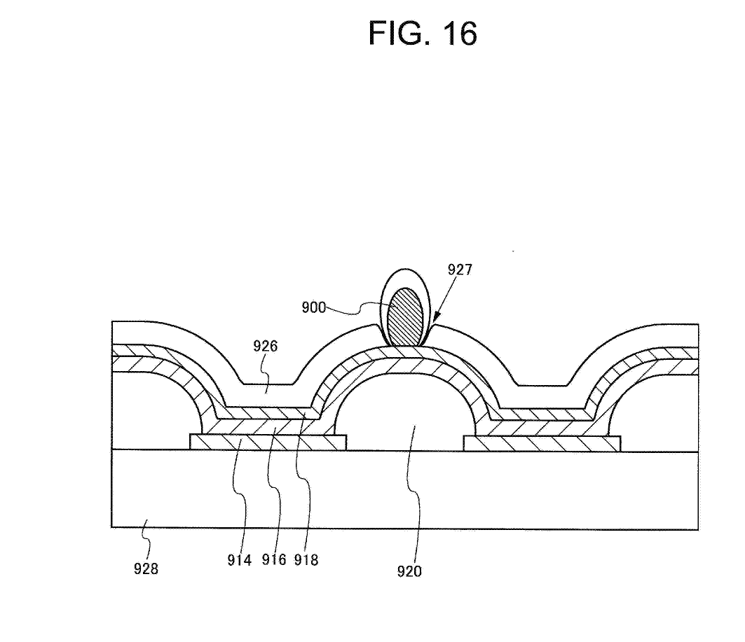

According to the present embodiment, after formation of the second electrode 118, since the attachment of foreign objects is suppressed, the organic layer 116 is securely covered by the passivation layer 126. On the other hand, if foreign objects 900 are attached to a formation surface of a first substrate 902, as is shown schematically in FIG. 16, a passivation layer 926 is not uniformly formed in this section and defective parts 927 are produced due to gaps or cracks where the layer is not attached. For example, at a stage up to the formation of a first electrode 914, organic layer 916 and second electrode 918, if foreign objects 900, its size is larger than the thickness of these layers, are present, defective sections as mentioned above are produced in the passivation layer 926. There is a risk that such foreign objects 900 significantly affect a light emitting region of a pixel even above an insulation layer 920. That is, if water which degrades the organic layer 916 infiltrates from this section, non-light emitting regions are occurred in a pixel, or non-light emitting pixels are occurred and it causes display defects.

According to the present embodiment, it is possible to arrange the second electrode 118 in each pixel 106 in the pixel part 104 and reduce the overall area, reduce the thickness of the second electrode 118, and due to these synergistic effects suppress the attachment of foreign objects before forming the passivation layer 126 which allows the size of foreign objects to be reduced. As a result, the passivation layer 126 can be uniformly arranged, and it is possible to suppress the occurrence of display defects due to non-light emitting pixels (dark spots)

As explained while referring to FIG. 2 and FIG. 3, the display device 100 related to one embodiment of the present invention includes a plurality of pixels 106 in the pixel part 104, and the conductive layer 124 arranged in a region between pixels. In addition, at least a part of the second electrode 118, which is one electrode forming a pixel 106, contacts with the conductive layer 124. The arrangement of the second electrode 118 and conductive layer 124 is explained in detail below.

### 3. Pixel Part Structure

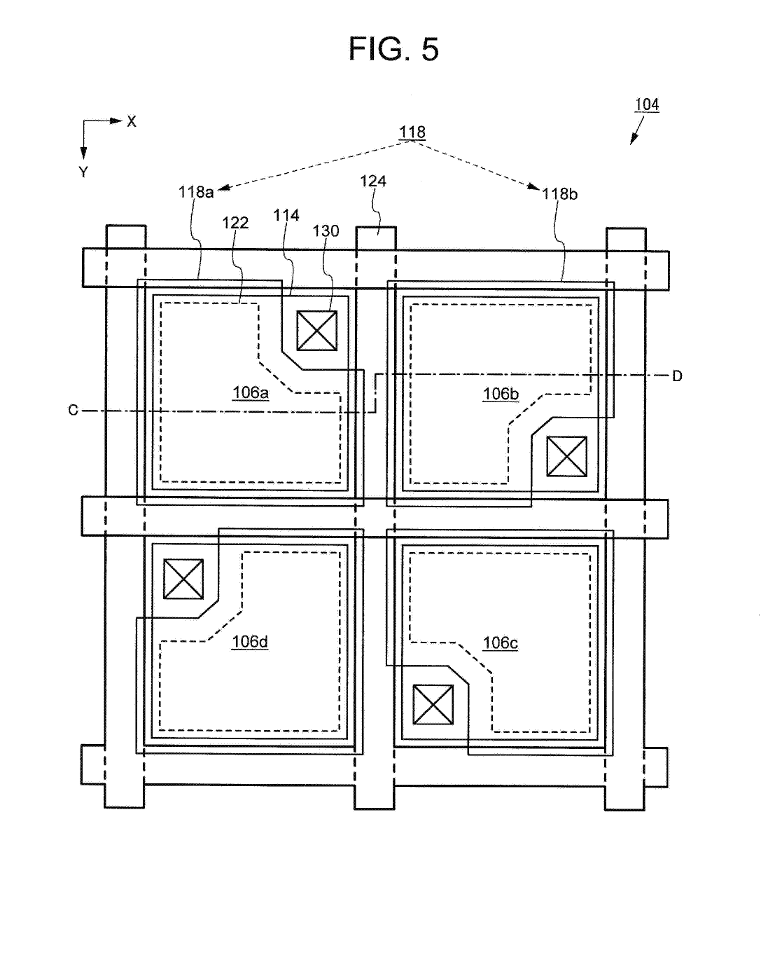

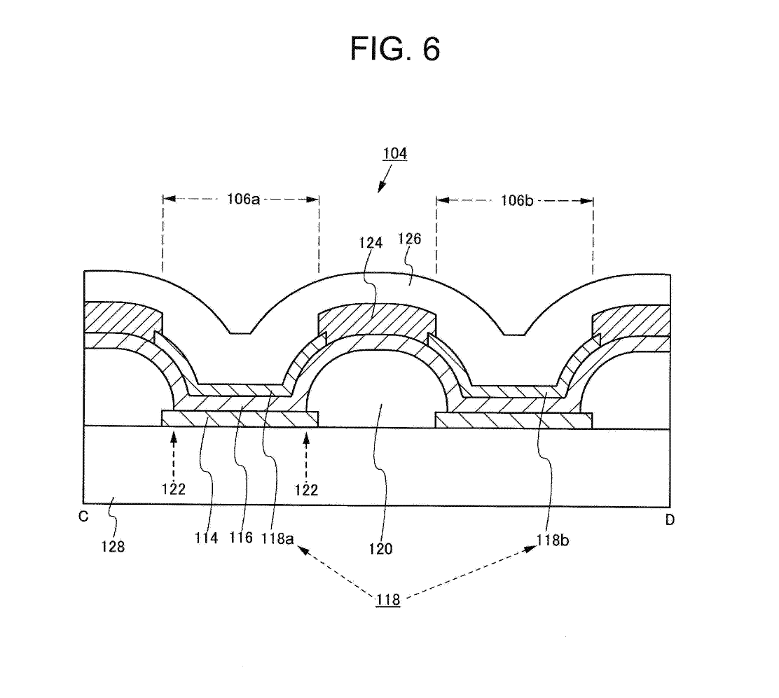

FIG. 5 shows a planar view of the pixel part 104. In addition, a cross-sectional structure corresponding to the line C-D shown in FIG. 5 is shown in FIG. 6.

FIG. 5 shows a form in which a first pixel 106a, second pixel 106b, third pixel 106c and fourth pixel 106d are arranged. The pixel 106 is arranged with the first electrode 114 and second electrode 118 opposing each other sandwiching the organic layer 116. The first electrode 114 is arranged separated for each pixel. The insulation layer 120 is arranged in these adjacent regions. The insulation layer 120 includes an open region 121 for exposing an upper surface of the first electrode 114, and the end part 122 of the cover region 123 is arranged above the first electrode 114.

In the example shown in FIG. 5 and FIG. 6, the conductive layer 124 is arranged to cover an end part of the second electrode 118. For example, the conductive layer 124 contacts the second electrode 118a of the first pixel 106a, and also contacts the second electrode 118b of the second pixel 106b. In this way, the conductive layer 124 is connected with a plurality of second electrodes 118. In this way, the second electrode 118 in each pixel 106 is controlled to the same voltage or essentially the same voltage. The conductive layer 124 is arranged extending in a first direction (X direction shown in FIG. 5) above the insulation layer 120, and also extending in a second direction (Y direction shown in FIG. 5) which intersects the first direction. In this way, by arranging the conductive layer 124 according to the arrangement of the pixels 106, it is possible to uniformly set the voltage (voltage of the second electrode 118) of each pixel in the pixel part 104.

Furthermore, although a form is shown in FIG. 5 in which the conductive layer 124 extends in the first direction and the second direction intersecting the first direction, the present invention is not limited to this form. For example, the conductive layer 124 may also be arranged in only the first direction or only in the second direction intersecting the first direction. In either case, by arranging the conductive layer 124 to link second electrodes 118, it is possible to control the voltage of the second electrode 118 in the pixel part 104 by a voltage applied to the conductive layer 124. In addition, it is possible to reduce the effects of a resistance loss due to reducing the thickness of the second electrode 118.

In the structure shown in FIG. 6, the second electrode 118 extends above the insulation layer 120 and contacts with the conductive layer 124. In this way, since the second electrode 118 and conductive layer 124 are in contact above the insulation layer 120, it is possible to prevent short circuits between the conductive layer 124 and first electrode 114. In addition, by providing the end part of the insulation layer 120 with an inclined surface, it is possible to provide a good contact between the second electrode 118 and conductive layer 124. By arranging the conductive layer 124 on an upper layer side of the second electrode 118, the organic layer 116 is protected by the second electrode 118 when manufacturing the conductive layer 124. The conductive layer 124 is manufactured by a thin layer manufacturing technique such as a sputtering method or vapor deposition method. In this case, it is preferred to use a shadow mask so that the conductive layer 124 is not formed in a light emitting region. The conductive layer 124 in FIG. 6 is arranged in a lattice shape as is shown in FIG. 5. In this case, layer formation of the conductive layer 124 may use a shadow mask having a stripe shaped open part divided into two patterns, one pattern extending in one direction and another pattern extending in an intersecting direction. By arranging the conductive layer 124 in alignment with a pattern of the insulation layer 120, it is possible to arrange the conductive layer 124 in the pixel part 104 without affecting the aperture ratio of a pixel. In addition, a conductive paste and a printing method may be used to form the conductive layer 124.

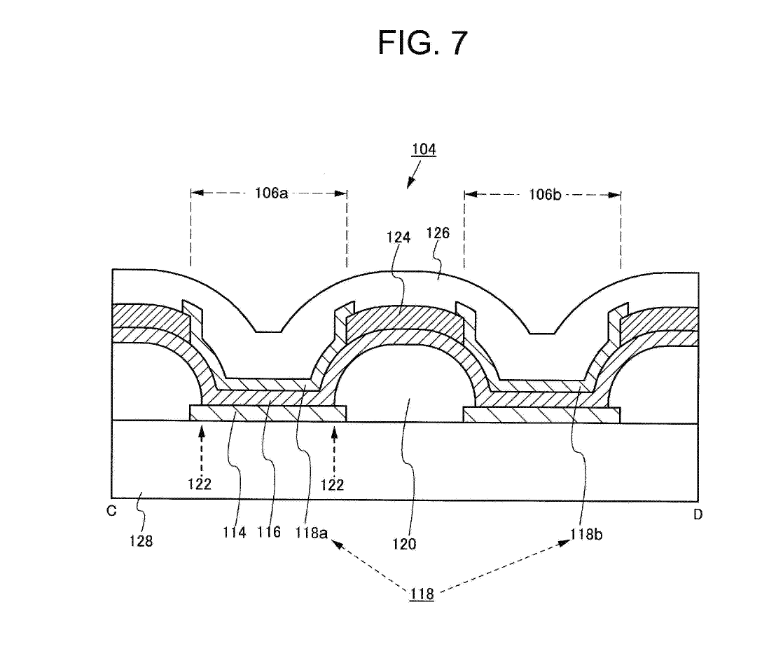

FIG. 7 shows a form in the case where the second electrode 118 is manufactured after arranging the conductive layer 124 above the insulation layer 120. An end part of the second electrode 118 is arranged at an upper part of the conductive layer 124. In this shape, since the second electrode 118 contacts a side end part and an upper surface part of the conductive layer 124, it is possible to increase contact area and reduce contact resistance.

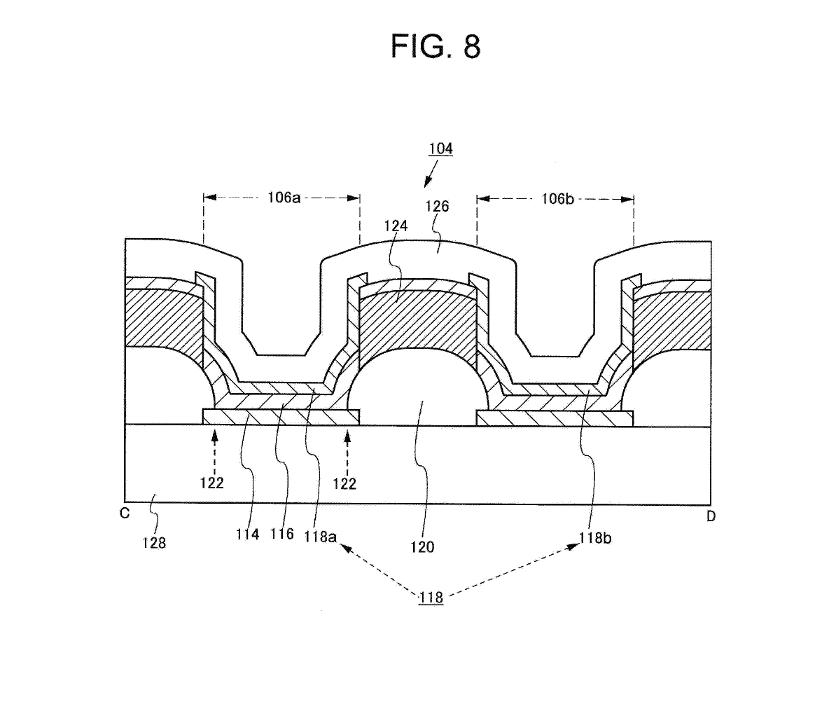

FIG. 8 shows a form in the case where the organic layer 116 and second electrode 118 are arranged after the conductive layer 124 is arranged above the insulation layer 120. According to this shape, the organic layer 116 is not yet formed when arranging the conductive layer 124. Thus, the organic layer 116 is never damaged in a formation process of the conductive layer 124. In addition, by increasing the layer thickness of the conductive layer 124, it is possible to arrange the organic layer 116 in a self-aligning manner with respect to each pixel. That is, since step covering properties of the organic layer 116 are poor when the organic layer 116 is formed by a vapor deposition method to a thickness of about 100 nm to 200 nm, the side surface of the conductive layer 124 is not sufficiently covered. Following this, by manufacturing the second electrode 118 using a sputtering method, it is possible to attach an ITO layer or IZO layer to a side surface part of the conductive layer 124 which is not covered by the organic layer 116. In this way, the conductive state between the second electrode 118 and conductive layer 124 is secured and it is possible to form an electrical connection.

In the case of each of FIG. 6, FIG. 7 and FIG. 8, the passivation layer 126 is arranged on an upper layer side of the second electrode 118. Since the attachment of foreign objects is suppressed even after manufacture of the second electrode 118, the passivation layer 126 protects the organic layer 116 and can suppress the occurrence of non-light emitting pixels (dark spots). It is not necessary to form the conductive layer 124 into a thick layer since a low resistance material is used as described above. Thus, the covering properties of the passivation layer 126 are not affected even when the conductive layer 124 is arranged above the insulation layer 120. That is, it is possible to ensure that the passivation layer 126 does not become too thin and that cracks do not occur due to a step of the conductive layer 124. In addition, if a shadow mask is used when manufacturing the conductive layer 124 by a sputtering method or vapor deposition method, the end part of the conductive layer 124 does not become a steep end surface due to step coverage of a cover layer at the time of formation, and it is possible to form a comparatively gentle inclined surface. In this way, it is possible to improve the step covering properties of the passivation layer 126.

In this way, according to one embodiment of the present invention, by arranging the conductive layer 124 above the insulation layer 120 which is a non-light emitting region of the pixel 106, and electrically conducting the conductive layer 124 with the second electrode 118 arranged in each pixel or in each of a plurality of pixels, it is possible to securely arrange the passivation layer 126, and suppress the occurrence of defects called dark spots in the pixel part 104.

### 4. Application Example

It is possible to apply the structure of a pixel electrode and conductive layer (auxiliary wiring) related to one embodiment of the present invention to various pixel arrangements. An example is shown below.

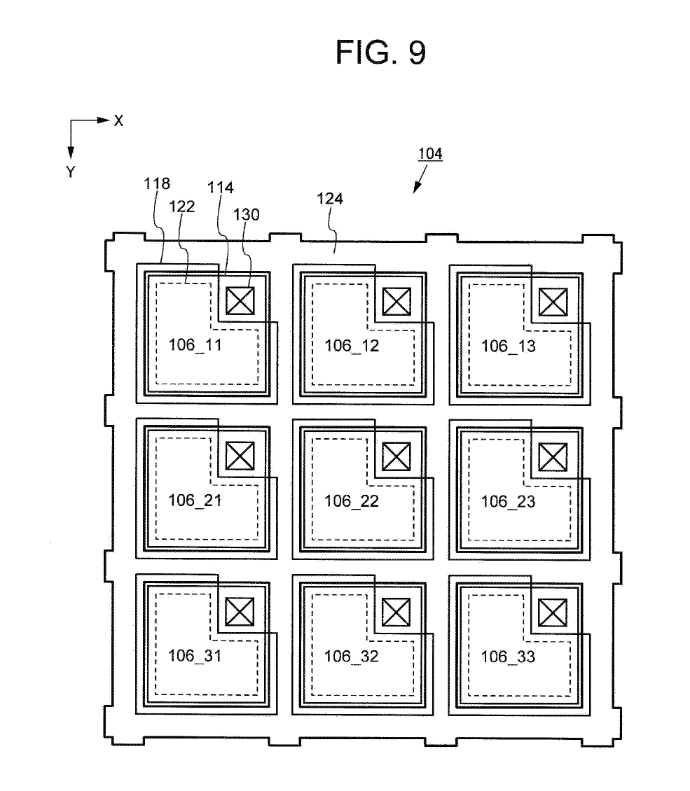

FIG. 9 shows an example of a pixel part with a stripe arrangement. That is, pixels 106_11, 106_21, 106_31 corresponding to red, pixels 106_12, 106_22, 106_32 corresponding to green, and pixels 106_13, 106_23, 106_33 corresponding to blue are arranged in a Y direction shown in FIG. 9. Furthermore, the example shown in FIG. 9 shows a form in which each pixel is arranged at equal intervals and the conductive layer 124 is arranged in both an X direction and Y direction.

In FIG. 9, pixels corresponding to each color may be alternately arranged to form a square arrangement. In a square arrangement, pixels corresponding to each color are alternately arranged. For example, in the case where pixel 106_11 corresponds to red, pixel 106_12 corresponds to green, and pixel 106_13 corresponds to blue, a pixel 106_21 is arranged to correspond to blue, a pixel 106_22 is arranged to correspond to red, and a pixel 106_23 is arranged to correspond to green. In this way, even when the arrangement of pixels corresponding to each color is different, it is possible to arrange the conductive layer 124 in regions between pixels.

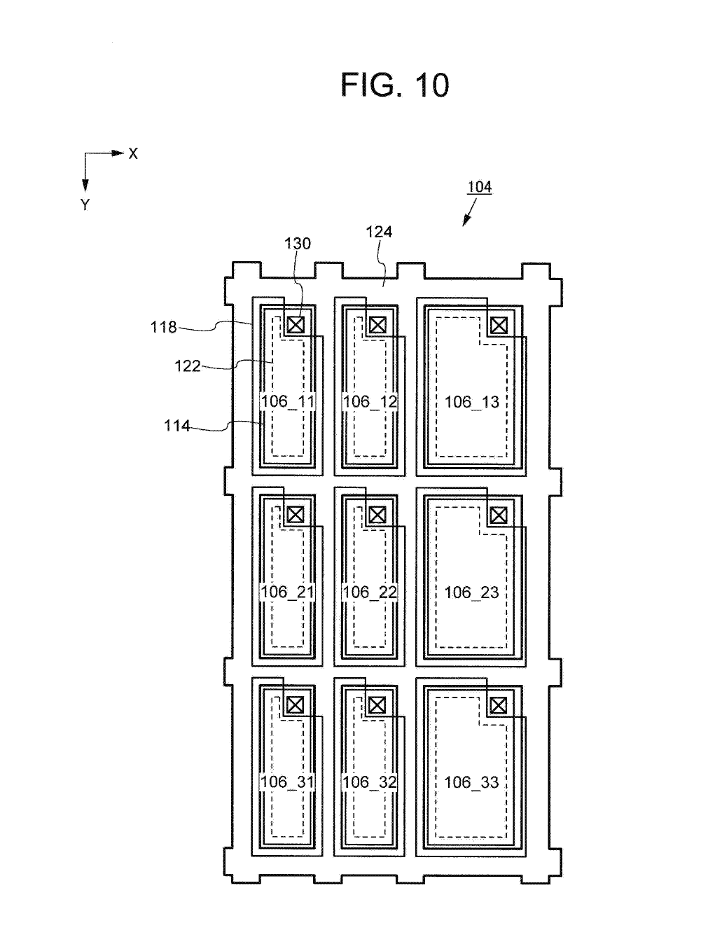

FIG. 10 shows a case in which pixels 106_13, 106_23, 106_33 corresponding to blue are arranged larger compared to other pixels in a square pixel arrangement. In this way, it is possible to arrange the conductive layer 124 in a region between pixels even when the size of some pixels is different.

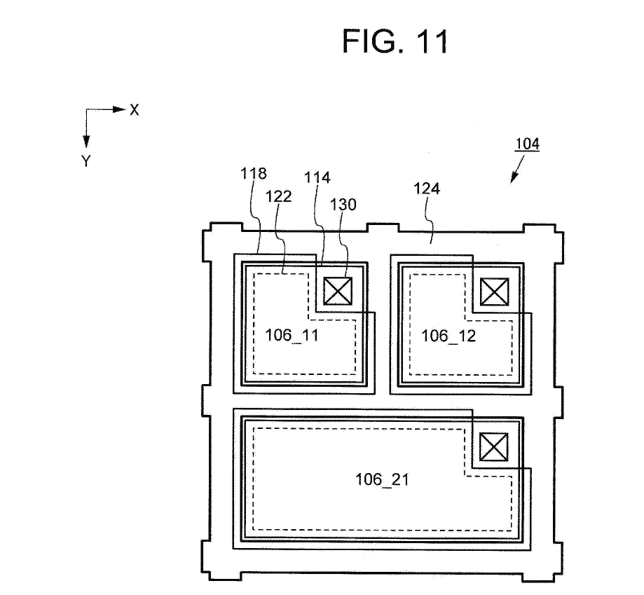

FIG. 11 shows a case in which a pixel 106_21 corresponding to blue is arranged larger than other pixels in a square pixel arrangement. In this way, it is possible to arrange the conductive layer 124 in a region between pixels even when the size of some pixels is different.

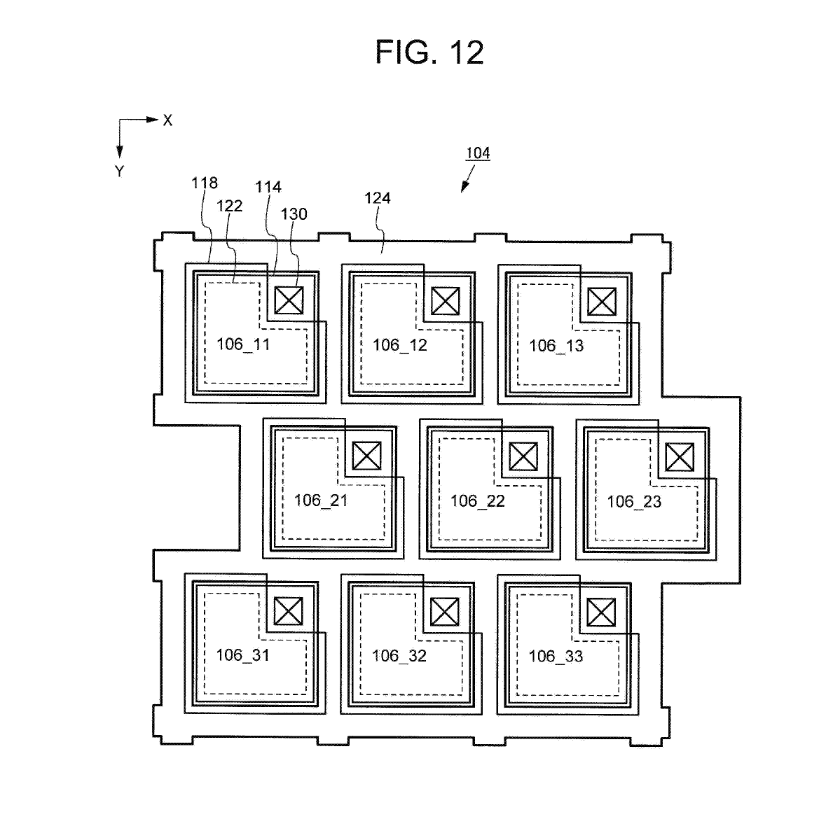

FIG. 12 shows an example of a pixel part with a delta arrangement. In a delta arrangement, pixels (pixels 106_11, 106_12, 106_13) belonging to a certain row, and pixels (pixels 106_21, 106_22, 106_23) belonging to an adjacent row are arranged misaligned by about half pitch. In this case, the conductive layer 124 cannot extend in a straight line with respect to a column direction. Therefore, in this case, the conductive layer 124 may be arranged only in a row direction, and a conductive layer extending in a column direction may be arranged aligned with a pixel arrangement so as to connect adjacent spaces of the conductive layer 124 extending in a row direction.

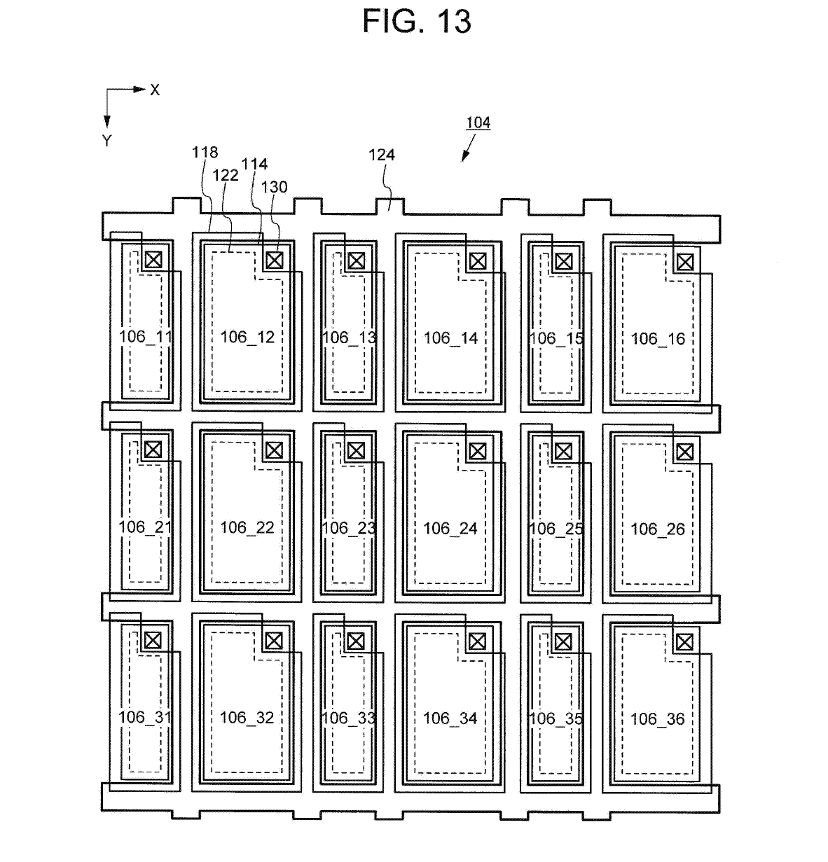

FIG. 13 shows an example of a pixel part in a pentile arrangement. In a pentile arrangement, pixels 106_12, 106_16, 106_24, 106_32, 106_36 corresponding to blue, or pixels 106_14, 106_22, 106_26, 106_34 corresponding to red are arranged between pixels 106_11, 106_13, 106_15, 106_21, 106_23, 106_25, 106_31, 106_33, 106_35 corresponding to green which has a high luminosity sensitivity. Pixels 106_12, 106_16, 106_24, 106_32, 106_36 corresponding to blue, or pixels 106_14, 106_22, 106_26, 106_34 corresponding to red have a larger area compared to pixels 106_11, 106_13, 106_15, 106_21, 106_23, 106_25, 106_31, 106_33, 106_35 corresponding to green.

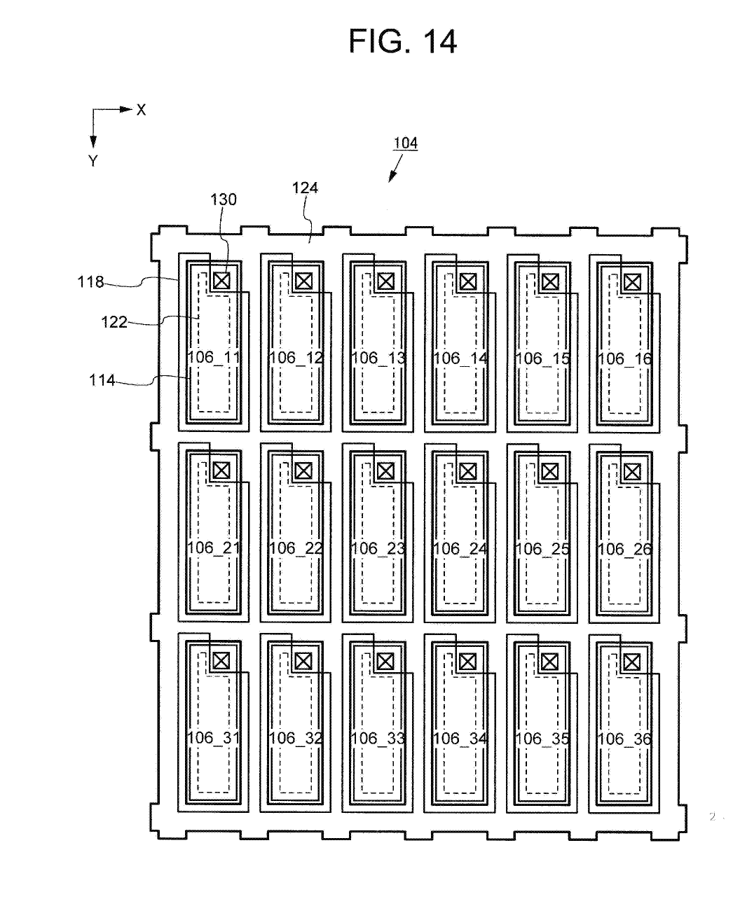

In addition, FIG. 14 shows an example in which some pixels corresponding to green (pixels 106_13, 106_21, 106_25, 106_33) are replaced with pixels corresponding to white in a pixel with a pentile arrangement.

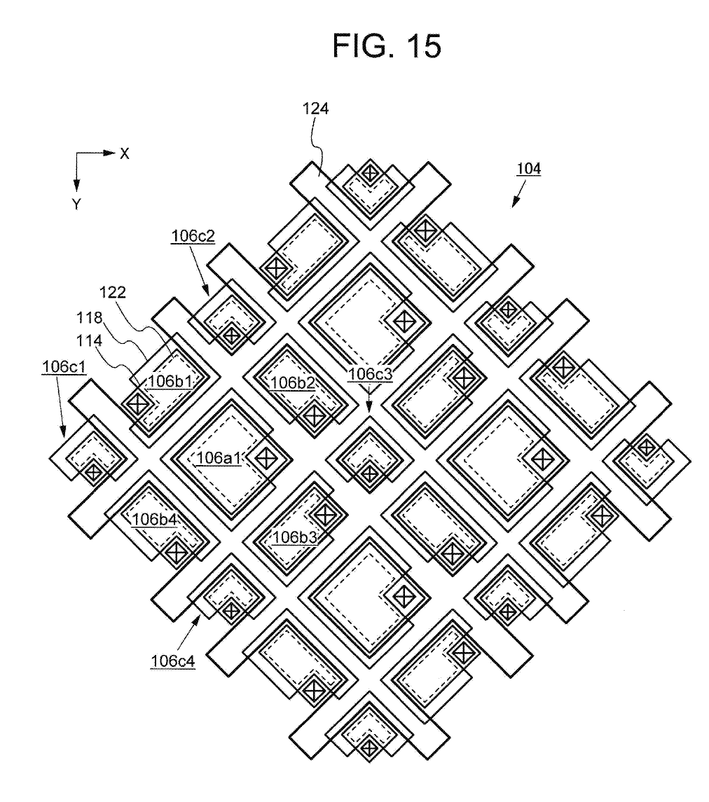

Furthermore, FIG. 15 shows a pixel arrangement called a diamond pentile in which pixels are arranged in a diagonal 45 degree direction in a pixel with a pentile arrangement. In the pixel arrangement shown in FIG. 15, pixels 106b1˜106b4 corresponding to green, and pixels 106c1˜106c4 corresponding to red are arranged around pixel 106a1 corresponding to blue.

In either FIG. 13, FIG. 14 or FIG. 15, pixels are arranged periodically and an insulation layer is arranged between the pixels. Therefore, it is possible to arrange a connection structure between the conductive layer 124 and second electrode 118 even in these pixel arrangements.

In this way, the structure of a pixel electrode and conductive layer (auxiliary wiring) related to one embodiment of the present invention can be applied to various pixel arrangements. In this way, it is possible to reduce display defects due to dark spots with respect to the display device 100 including each type of pixel arrangement.

What is claimed is:

1. A display device comprising:
a first electrode;
an insulation layer including an opening region exposing an inner side region of the first electrode, and a cover region covering regions apart from an inner side region of the first electrode, an end part of the cover region overlapping with a periphery edge part of the first electrode;
an organic layer above the first electrode;
a second electrode arranged opposite the first electrode and corresponding to the opening region of the insulation layer above the organic layer; and
a conductive layer above the cover region of the insulation layer and at least a part of the second electrode and the conductive layer are in contact.

2. The display device according to claim 1, wherein an end part of the second electrode is in contact with a part of the conductive layer, and an end part of the conductive layer is in contact with a part of the second electrode.

3. The display device according to claim 1, wherein the second electrode and the conductive layer contact in a region overlapping the insulation layer.

4. The display device according to claim 1, wherein an end part of the cover region of the insulation layer includes an inclined surface in a cross-sectional view, and the second electrode and the conductive layer contact on the inclined surface.

5. The display device according to claim 1, wherein the conductive layer contacts with the second electrode from an upper layer side of the second electrode.

6. The display device according to claim 1, wherein the first electrode has light reflecting properties and the second electrode has translucency.

7. The display device according to claim 6, wherein the second electrode includes conductive metal oxide, and the conductive layer includes metal.

8. The display device according to claim 7, wherein the second electrode has a thickness of 50 nm or more and 100 nm or less.

9. The display device according to claim 1, wherein a passivation layer is included on an upper surface of the second electrode and the conductive layer.

10. A display device comprising:
a plurality of pixels;
a pixel region including the plurality of pixels;
each of the plurality of pixels includes a light emitting element stacked with a first electrode, an insulation layer and a second electrode;
the pixel region includes
an insulation layer in each of the plurality of pixels, the insulation layer having an opening region exposing an inner side region of the first electrode, and a cover region covering regions apart from an inner side region of the first electrode, an end part of the cover region overlapping with a periphery edge part of the first electrode; and
a conductive layer extending along the plurality of pixels above the cover region of the insulation layer; the second electrode and the conductive layer being electrically connected.

11. The display device according to claim 10, wherein an end part of the second electrode contacts an end part of the conductive layer.

12. The display device according to claim 10, wherein the second electrode and the conductive layer contact in a region overlapping the insulation layer.

13. The display device according to claim 10, wherein an end part of the cover region of the insulation layer includes an inclined surface in a cross-sectional view, and the second electrode and the conductive layer contact at the inclined surface.

14. The display device according to claim 10, wherein the conductive layer contacts with the second electrode from an upper layer side of the second electrode.

15. The display device according to claim 10, wherein the second electrode is arranged in each of the plurality of pixels and connected via the conductive layer.

16. The display device according to claim 10, wherein the first electrode has light reflecting properties and the second electrode has translucency.

17. The display device according to claim 16, wherein the second electrode includes conductive metal oxide and the conductive layer includes metal.

18. The display device according to claim 17, wherein the second electrode has a thickness of 50 nm or more and 100 nm or less.

19. The display device according to claim 10, wherein the plurality of pixels are arranged in a first direction and a second direction intersecting the first direction, the conductive layer extending in the first direction and the second direction.

20. The display device according to claim 10, wherein a passivation layer is included on an upper surface of the second electrode and the conductive layer.
